(19) United States
(12) Patent Application Publication
(10) Pub. No.: US 2026/0330106 A1
(43) Pub. Date: Oct. 22, 2026

(54) Systems and Methods for Generating, Evaluating, and Fabricating Camouflage Patterns Using Artificial Intelligence and Material Simulation

(71) Applicant: Forest Outfitters, LLC, Sparks, NV (US)

(72) Inventors: Zachary W. Paschall, Sparks, NV (US); Darrell Whitelaw, Flagstaff, AZ (US)

(21) Appl. No.: 19/651,326

(22) Filed: Apr. 17, 2026

Related U.S. Application Data
(60) Provisional application No. 63/790,275, filed on Apr. 17, 2025.
(60) Provisional application No. 63/802,766, filed on May 9, 2025.

(51) Int. Cl. G06F 30/27

(52) U.S. Cl. CPC G06F 30/27

(57) ABSTRACT

Systems and methods disclosed herein generate and test camouflage patterns using generative machine learning models and adversarial detection loops to iteratively minimize visual and spectral detectability. The camouflage patterns may be optimized for various textiles, electronic materials, technology or sensors simulating real-world conditions such as stretch, folding, weathering, and thermal variation.

### CROSS-REFERENCE TO RELATED APPLICATIONS

This application claims the benefit of and priority to U.S. Provisional Patent Application Nos. 63/790,275, filed Apr. 17, 2025, and 63/802,766, filed May 9, 2025, each of which is hereby incorporated by reference in its entirety.

### STATEMENT REGARDING FEDERALLY SPONSORED RESEARCH

None.

### FIELD OF THE INVENTION

This disclosure relates to the use of artificial intelligence to design, generate, evaluate, and fabricate virtual and physical camouflage patterns. The systems and methods described herein are optimized for multi-spectrum concealment and/or material compatibility.

### BACKGROUND

Traditional camouflage is based on repeating solid color and shape patterns, typically designed through manual artistry, printed onto fabric in a two-dimensional motif. Such patterns fail to account for complex visual and spectral environments, and often do not fool a discerning eye.

Further, modern adversaries no longer rely solely on the human eye. They utilize computer vision, motion detection, multi-spectral scanning and artificial intelligence (AI) to calculate a probability that an object represents an unnatural object or threat. Traditional camouflage does not account for the use of advanced detection instrumentation and techniques.

### SUMMARY

The present disclosure relates to systems and methods for generating camouflage patterns. The systems and methods leverage generative machine learning models and adversarial detection loops to iteratively minimize visual and spectral detectability. In some embodiments, the final camouflage pattern is optimized for various textiles, simulating real-world conditions such as stretch, folding, weathering, and thermal variation. The outputs are printable camouflage patterns suitable for field deployment without reliance on embedded sensors or digital logic.

The presently disclosed camouflage patterns are quantitatively shown to defeat detection systems. Each pattern is generated against AI vision systems, environmental simulations, and silhouette-recognition tools.

In an aspect, a method for creating a camouflage pattern comprises: inputting data into a camouflage pattern generator; using the camouflage pattern generator to generate a camouflage pattern for a target environment; applying the camouflage pattern to an object to create a camouflaged object; placing the camouflaged object in a virtual version of the target environment; determining a probability that the camouflaged object is present in the virtual version of the target environment; and, when the probability is below a specified threshold, identifying the camouflage pattern as effective for eliminating an object's signature or for evading detection of the camouflaged object.

In an embodiment, the method for creating a camouflage pattern is carried out by a generative machine learning model. In an embodiment, the generative machine learning model is selected from the group consisting of a generative adversarial network (GAN), a diffusion model, a flow-matching network, a variational autoencoder, and a transformer-based model.

In an embodiment, a method for creating a camouflage pattern further comprises adding noise to the camouflage pattern before applying the camouflage pattern to the object. Exemplary types of noise include, but are not limited to, Perlin noise, visual texture banding, simplex noise, learned latent noise and combinations thereof.

In an embodiment, the data comprise images of a portion of an animal, an entire animal, hair, feathers, stripes, a landscape, a tree(s), leaves, rock(s), water, or a combination thereof. In an embodiment, the data are selected for the target environment. For example, the data may be selected for a season of the year, time of day, anticipated shade patterns, and the like.

In an embodiment, the object is a real object in a real or virtual environment. In an embodiment, the object is a real or virtual object in a real or virtual environment. In an embodiment, the object is an animate or inanimate object. For example, the object may be selected from the group consisting of a human form (real or avatar), a watercraft, diving equipment, a land vehicle, an aircraft and/or a part of any of the foregoing.

In an embodiment, the real or virtual object physically transforms as a function of time and space and/or moves in the virtual target environment. For example, a human or animal may bend its joints to facilitate movement, a drone may hoover or traverse between locations, a tank may rotate its track, etc.

In an embodiment, a method for creating a camouflage pattern further comprises applying the camouflage pattern to a substrate, and the step of applying may be performed in multiple layers to achieve macroscopic texturing. Suitable substrates include, but are not limited to, plastic, paper, metal, glass, and/or fabric. In some embodiments, these substrates may be embossed or woven.

In an embodiment, a method for creating a camouflage pattern further comprises adding a macro pattern to the camouflage pattern to form a hybrid pattern that visually breaks-up the object's form. Typically, the hybrid pattern is non-repeating and the macro pattern is lighter than the camouflage pattern.

In an embodiment, a camouflage pattern may comprise lightened areas where the human form bends or where an object comprises moving parts.

In an aspect, a hybrid camouflage pattern comprises a camouflage pattern based on an image of animal hair and a macro pattern that breaks the camouflage pattern into non-repeating segments.

In an aspect, a garment or overwrap has a hybrid camouflage pattern comprising a camouflage pattern based on an image of animal hair and a macro pattern that breaks the camouflage pattern into non-repeating segments printed thereon. For example, the hybrid camouflage pattern may be 3-D printed as a stand-alone item, garment, or overwrap or the hybrid camouflage pattern may be 3-D printed onto an existing substrate.

In an embodiment, a material upon which a camouflage pattern disclosed herein is applied comprises at least one of a thermally emissive layer, a spectrally selective coating, or a conductive fiber system. In an embodiment, a camouflage pattern is generated with the spectral properties of the material included in the model.

In an aspect, a method for generating a camouflage pattern comprises: training a generative machine learning model on environment-specific data; applying the camouflage pattern to a simulated form within a 3-D virtual environment; evaluating visibility of the simulated form using multi-spectrum detection models; and optimizing the camouflage pattern until detection probability falls below a predefined threshold. In an embodiment, the generative machine learning model is selected from the group consisting of a generative adversarial network (GAN), a diffusion model, and a transformer-based architecture.

In an embodiment, the step of evaluating comprises detecting visible, infrared, and/or ultraviolet spectra.

In an embodiment, a method for generating a camouflage pattern comprises simulating the camouflage pattern under textile conditions including stretching, folding, and/or heat exposure.

In an aspect, a system for generating camouflage comprises: a generative engine for pattern creation; a simulation module for modeling material impact; and an optimization loop refining concealment properties without embedded sensors.

In an aspect, a system for generating camouflage comprises: a generator of patterns; a discriminator that assigns a detection probability score to each pattern; and a logic unit that accepts patterns for implementation only if the probability score is below a predefined threshold.

In an aspect, a system disclosed herein accepts three-dimensional body scan or object scan data captured via structured light scanning, photogrammetry, or depth-camera array. The scan data is processed to generate a personalized/unique surface mesh representing a user's or object's physical dimensions and proportions. A camouflage pattern generator maps the generated pattern onto this surface mesh using UV unwrapping, such that pattern elements align continuously across seams and articulation points. The mapped pattern is output as a print-ready file formatted for direct-to-fabric digital printing, digital embroidery, or cut-and-sew production, enabling garment production tailored to an individual user's body geometry or object's shape.

### BRIEF DESCRIPTION OF THE DRAWINGS

Illustrative embodiments of the present invention are described in detail below with reference to the attached drawings.

FIG. 1 depicts a traditional camouflage pattern on a human form.

FIG. 2 depicts a hybrid camouflage pattern, according to the present disclosure, on a human form.

FIG. 3 is a block diagram illustrating components of a system for generating camouflage patterns, according to the present disclosure.

FIG. 4 is a flowchart illustrating steps in a method for creating a camouflage pattern, according to the present disclosure.

FIG. 5 illustrates a plurality of camouflage patterns generated by the systems and methods disclosed herein shown in their target environments.

### DETAILED DESCRIPTION

In general, the terms and phrases used herein have their art-recognized meaning, which can be found by reference to standard texts, journal references and contexts known to those skilled in the art. The following definitions are provided to clarify their specific use in the context of this description.

As used herein, a “generative machine learning model” is a statistical model of the conditional probability of an observable variable given a target variable, where the learned conditional probability distribution of training data can be applied to new data to generate an output that resembles the original training data. Generative machine learning models disclosed herein utilize (A) a generative neural network trained on environmental and/or biological data to produce camouflage patterns that are specific to a selected target environment and (B) a convolutional neural network trained to detect signatures of humans and objects and to determine a probability that the human or object exists in the target environment. For example, the environmental data may be terrain imagery or data, foliage imagery or data, and/or seasonal environmental data and the biological data may be biological texture data, such as animal fur and/or feathers.

As used herein, a “generative adversarial network” (GAN) comprises two neural networks-a generator and a discriminator-that compete to fool one another. Traditionally, GAN generators have been used to create images and other content that the discriminator cannot tell are synthetic/fake. An adversarial loop allows both networks to be trained simultaneously, such that the generator improves its ability to create realistic content and the discriminator improves its ability to detect synthetic/fake content.

As used herein, a “diffusion model”, “diffusion-based generative model”, or “score-based generative model” refers to a machine learning model that learns a diffusion process for a given dataset and uses that process to generate new elements that are distributed similarly to the original dataset.

As used herein, a “flow-matching network” refers to refers to a generative model that learns a continuous normalizing flow by matching vector fields that transport a simple prior distribution to a target data distribution, enabling efficient sampling and training without the iterative denoising steps required by diffusion models

As used herein, a “variational autoencoder” refers to a generative model comprising an encoder network that maps input data to a learned latent probability distribution and a decoder network that samples from that distribution to reconstruct or generate output data, enabling controlled generation through manipulation of the latent space.

As used herein, a “transformer-based model” refers to a neural network model that processes input data—including sequential, spatial, or multi-modal data—using self-attention mechanisms that capture contextual relationships across the full input simultaneously. Transformer-based models have been applied to image synthesis tasks wherein image patches or latent representations are tokenized and processed through multi-head attention layers to generate high-fidelity visual output.

As used herein, a human or object “signature” refers to data that indicates the presence of a real or virtual human form or object. Exemplary types of signatures or data include one or more of visual data (e.g., silhouettes), electromagnetic data (e.g., thermal data), sound, movement measurements, and chemical detection (e.g., detection of hydrocarbon molecules may indicate fuel from a vehicle).

As used herein, a “target environment” is a specific setting or terrain type where a human and/or an object will be deployed and concealment is desirable.

The present disclosure relates to the use of artificial intelligence to produce camouflage patterns that make a human or object signature within a target environment nearly undetectable to a trained model. Particularly, a generator of a generative machine learning model is used to create a camouflage pattern that is applied to a human or object placed in a target environment. An evaluation module then assesses the target environment to determine a probability that a human or object is present. If the probability is below a predefined threshold (e.g., 20% or less, 15% or less, 10% or less, 5% or less, 1% or less), the camouflage pattern is identified as effective for eliminating a human or object signature within the target environment.

In an embodiment, an evaluation module or discriminator module comprises a convolutional neural network trained on a labeled dataset comprising: (i) environmental imagery or other data captured across target terrain types including woodland, desert, alpine, and littoral environments; (ii) synthetic composite images or other data generated by rendering human forms or other target objects with known camouflage patterns against environmental backgrounds; and, optionally, (iii) augmented samples produced via procedural noise injection and color-space variation to expand training distribution and improve generalization across unseen terrain types and lighting conditions. The procedural noise may, for example, be Perlin noise, simplex noise, learned latent noise, or the like.

The virtual target environment used for discriminator evaluation is a physics-informed rendering environment that simulates naturalistic lighting conditions including variable sun angle, cloud cover, shadow casting, and seasonal foliage density. The discriminator outputs a scalar detection probability score representing the likelihood that a human form or target object is present in the rendered scene. Camouflage patterns for which the detection probability is less than or equal to a predetermined threshold-for example, one percent or less-are accepted as meeting the stealth criterion. Patterns that do not meet the threshold are returned to the generator for iterative refinement. The number of refinement iterations and the acceptance threshold are programmable parameters that may be adjusted based on application requirements.

### Multi-Spectral Embodiments

In some embodiments, the discriminator module is trained on multi-spectral imagery including near-infrared, shortwave infrared, and thermal infrared bands in addition to visible-spectrum data. In these embodiments, the camouflage pattern generator produces patterns optimized for concealment across multiple detection modalities simultaneously. The fabric or material upon which the pattern is applied may incorporate thermally emissive or reflective layers, conductive fiber systems, or spectral-selective coatings that cooperate with the generated pattern to reduce detectability across non-visible wavelengths. The AI-generated pattern is adapted to account for the spectral signature of the underlying material, such that the combined system minimizes cross-spectral detectability against sensors operating in visible, infrared, and/or thermal bands. Exemplary methods for generating, evaluating, and deploying camouflage patterns according to the present disclosure may include one or more of the following steps:
1. Data Ingestion and Simulation: Input comprises multimodal data including at least one of semantic descriptors, multispectral imagery (e.g., RGB, IR, UV), synthetic datasets, and spatial representations of target environments and target object forms.
2. Pattern Generation Engine: A generative machine learning model generates a base camouflage pattern using training data from multiple environments.
3. Detection Optimization Loop: A trained detection model evaluates the camouflaged form for visibility across multiple spectra. Patterns failing to conceal the form below a threshold are refined.
4. Material Simulation Engine: The camouflage pattern is simulated on materials such as cotton, ripstop nylon, mesh, and dynamic materials. This stage includes modeling for shadowing, stretching, folding, and heat dispersion.
5. Final Output: Once validated through simulation, the pattern is exported for use in textile printing or lamination on physical products such as, but not limited to, uniforms, equipment covers, or gear.

In some embodiments, the disclosed camouflage patterns may be subjected to computational noise and/or overlapped with a macro pattern that visually breaks-up the human body or object to conceal movement at articulating portions of the human body or object.

In an embodiment, the disclosed camouflage patterns are printed on material that is three-dimensionally textured (e.g., embossed or woven). In an embodiment, the camouflage patterns are dyed, printed or painted in a way that creates a three-dimensional texture on a fabric or surface. In an embodiment, fabric upon which the camouflage patterns disclosed herein are disposed may be face material optionally overlaying a membrane and/or a liner. In an embodiment, at least one of the layers may produce a thermal or energy masking function. Such materials include, but are not limited to, those containing a substantially continuous system of conductive fibers combined with a non-conductive fabric. Exemplary materials are disclosed, for example, in U.S. Pat. Nos. 8,410,461, 8,188,452 and 8,203129, each of which is incorporated by reference herein. In an embodiment, a dynamic material capable of changing from one camouflage pattern to another camouflage pattern on-the-fly or on demand is used. Such “chameleon” implementations are possible with the use of materials, such as those disclosed in D. Castelvecchi, “Octopus-inspired ‘synthetic skin’ changes colour and texture on demand”, Nature, 649, 540 (2026) and Stanford Report, “New material changes color and texture like an octopus,” Jan. 7, 2026, news.stanford.edu/stories/2026/01/flexible-material-changes-color-texture-camouflage-robotics-research?utm_content=httpsnewsstanfordedustories202601flexiblematerialchangescolortexturecamouflageroboticsresearch&utm_source=feedotter&utm_medium=email&utm_campaign=ext-01-07-2026.

Those of skill in the art will appreciate that while this disclosure focuses on camouflaging a human body, other objects, including inanimate objects, may be concealed by the methods, patterns, techniques and fabrics disclosed herein. Exemplary inanimate objects that may be camouflaged by the patterns and methods disclosed herein include, but are not limited to, watercraft, diving equipment, land vehicles, aircraft and/or parts thereof.

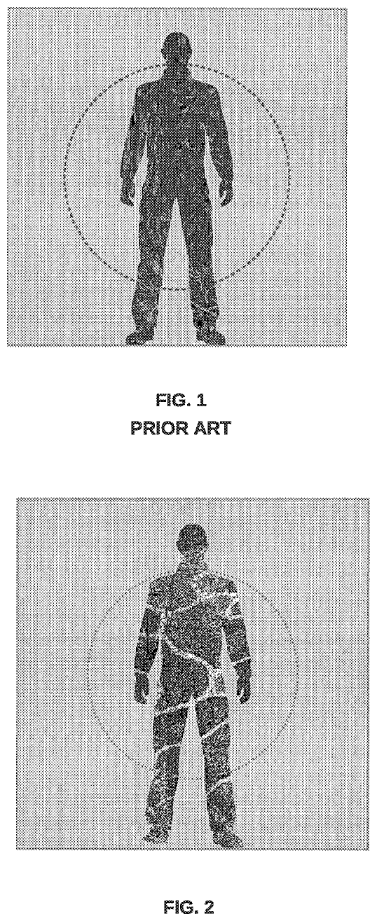

FIG. 1 depicts a traditional camouflage pattern on a human form. The traditional camouflage pattern is based solely on landscape elements (e.g., trees, leaves, sticks), and it is provided as a flat, two-dimensional, non-texturized rendering. The traditional camouflage pattern does not include a macro pattern (e.g., a large-scale, non-uniform, vein-like pattern) or other strategically placed lighter hued areas that help conceal movement at flex points of the human body. For example, prior to, during or after pattern generation, a macro pattern template may be applied to the surface of the human form or object. The macro pattern template comprises a non-repeating geometric segmentation that divides the surface into irregular regions having boundaries that do not correspond to anatomically recognizable outlines such as shoulder edges, torso boundaries, or limb contours. In an embodiment, the segmentation is computed by applying an irregular polygon mesh or Voronoi tessellation to a three-dimensional avatar surface, with region boundaries weighted to bisect high-recognition anatomical zones including shoulder lines, waist, and head-body junctions. By neutralizing the recognizable silhouette, the macro pattern template prevents the generated camouflage pattern from inadvertently reinforcing human body outlines through tonal or color boundaries that align with anatomical features.

FIG. 2 depicts an example of a hybrid camouflage pattern, according to the present disclosure, on a human form. The hybrid camouflage pattern is based on an image of animal hair, and optionally other natural elements, such as landscape elements. A macro pattern, which appears as a large-scale, non-uniform, vein-like pattern, breaks the camouflage pattern into non-repeating segments.

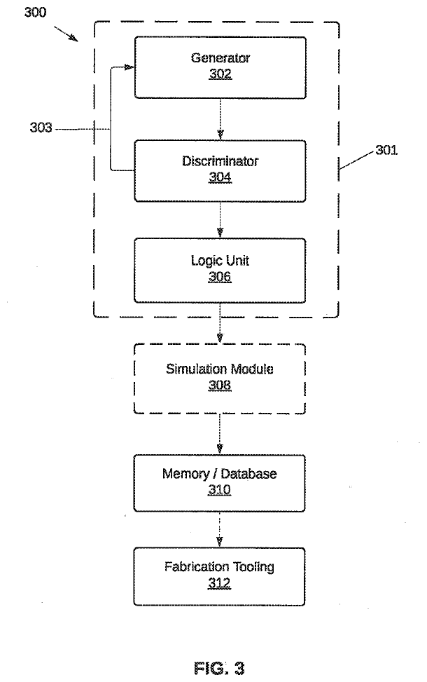

FIG. 3 is a block diagram illustrating components of a system 300 for generating camouflage patterns, according to the present disclosure. A generator or generative engine 302 creates patterns, which are sent to a discriminator 304 that applies the pattern to an object in a virtual target environment, attempts to detect the patterned object in the target environment within one or more ranges of the electromagnetic spectrum (e.g., visible and non-visible ultraviolet, infrared), and assigns a detection probability score to each pattern. The detection probability score may be a cumulative score across all spectral ranges or one or more individual scores for each portion of the spectrum. For example, individual scores may be used to identify patterns that can be implemented cost effectively for a specific portion of the electromagnetic spectrum, when defeating detection across multiple spectral ranges is unnecessary (e.g., hunting camouflage typically does not need to defeat infrared detection). The detection probability score is returned to the generator through an optimization or adversarial loop 303 to improve the patterns being created by the generator 302. If the detection probability score is sufficiently low (i.e., below a predefined threshold) a logic unit 306 accepts the pattern for use in the manufacture of a stand-alone material or as a coating on a substrate. Together, the generator 302, discriminator 304 and logic unit 306 form a generative machine learning model 301 implemented on a local or cloud-based processor.

Optionally, a simulation module 308 models material impact, such as flexibility, stretchability, breathability, texture, etc. Some material properties will impact detection directly. For example, materials with 3-D texture may mimic natural materials and lower detection probability scores. Other materials may be desirable for specific use cases, e.g., waterproofness for humid environments. Still other materials may advantageously decrease detectability by limiting noise produced by fabric during movement. For such materials, the simulation module may model sound.

Patterns from the logic unit 306 and data from the simulation module 308 may be stored in a memory or database 310. To manufacture a camouflage pattern that has been generated, tested, and approved by system 300, data from memory 310 may be transmitted to fabrication tooling 312. Fabrication tooling 312 may be independent from system 300, and may include, for example, a weaving or knitting machine, a 2D printer, a 3D printer, or a painting device.

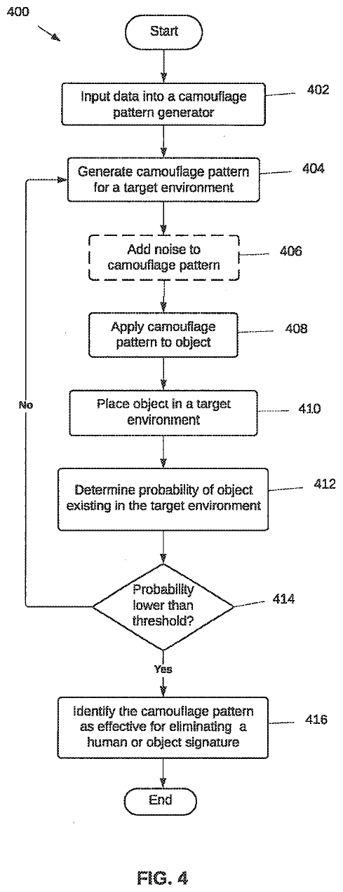

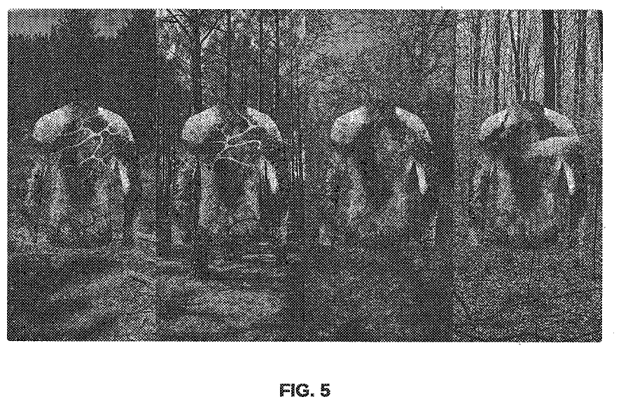

FIG. 4 is a flowchart 400 illustrating steps in a method for creating a camouflage pattern, according to the present disclosure. In step 402, images are input into a camouflage pattern generator, such as generator 302 of FIG. 3. Exemplary images include a portion of an animal, an entire animal, hair, feathers, stripes, a landscape, a tree(s), leaves, rock(s), water, or a combination thereof. Typically, the images are selected for a specific target environment) and optionally for a season of the year, a time of day, sensor threat, etc. In step 404, the generator creates a camouflage pattern for a target environment from the images. Optionally, noise is added to the camouflage pattern, in step 406. In step 408, the camouflage pattern is applied to a real or virtual object, such as a human form, a watercraft, diving equipment, a land vehicle, or an aircraft. In step 410, the camouflaged object is placed in a real or virtual target environment, and in step 412, a probability that the object exists in the target environment is determined. For example, discriminator 304 of the generative machine learning model 301 assigns a detection probability score. Step 414, queries whether the probability of detection is lower than a threshold. If the answer is “no”, the method reverts to step 404, and a new camouflage pattern is generated and tested. If the answer is “yes”, the camouflage pattern is identified as effective for eliminating a human or object signature (i.e., the human or object is considered virtually undetectable in the target environment). The camouflage patterns identified in step 416 may, for example, be saved in memory/database 310 of system 300 of FIG. 3.

FIG. 5 illustrates a plurality of camouflage patterns generated by the systems and methods disclosed herein shown in their target environments. The target environments show various flora and seasons. All four camouflage patterns have lighter hues at areas of the human form that move (e.g., shoulders, elbows, waist, wrists), and the two leftmost patterns contain macro patterns, which are a series of large-scale, non-uniform, curvilinear lines, that break the base pattern into non-repeating units.

### Statements Regarding Incorporation by Reference and Variations

All references cited throughout this application, for example patent documents including issued or granted patents or equivalents; patent application publications; and non-patent literature documents or other source material; are hereby incorporated by reference herein in their entireties, as though individually incorporated by reference, to the extent each reference is at least partially not inconsistent with the disclosure in this application (for example, a reference that is partially inconsistent is incorporated by reference except for the partially inconsistent portion of the reference).

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the invention has been specifically disclosed by preferred embodiments, exemplary embodiments and optional features, modification and variation of the concepts herein disclosed can be resorted to by those skilled in the art, and that such modifications and variations are considered to be within the scope of this invention as defined by the appended claims. The specific embodiments provided herein are examples of useful embodiments of the invention and it will be apparent to one skilled in the art that the invention can be carried out using a large number of variations of the devices, device components, and method steps set forth in the present description. As will be apparent to one of skill in the art, methods and devices useful for the present methods and devices can include a large number of optional composition and processing elements and steps. All art-known functional equivalents of materials and methods are intended to be included in this disclosure. Nothing herein is to be construed as an admission that the invention is not entitled to antedate such disclosure by virtue of prior invention.

When a group of substituents is disclosed herein, it is understood that all individual members of that group and all subgroups are disclosed separately. When a Markush group or other grouping is used herein, all individual members of the group and all combinations and subcombinations possible of the group are intended to be individually included in the disclosure.

It must be noted that as used herein and in the appended claims, the singular forms “a”, “an”, and “the” include plural reference unless the context clearly dictates otherwise. Thus, for example, reference to “a garment” includes a plurality of such garments and equivalents thereof known to those skilled in the art, and so forth. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

Unless defined otherwise, all technical and scientific terms used herein have the same meanings as commonly understood by one of ordinary skill in the art to which this invention belongs. Although any methods and materials similar or equivalent to those described herein can be used in the practice or testing of the present invention, the preferred methods and materials are described.

Whenever a range is given in the specification, for example, a range of integers, a temperature range, a time range, a composition range, or concentration range, all intermediate ranges and subranges, as well as all individual values included in the ranges given are intended to be included in the disclosure. As used herein, ranges specifically include the values provided as endpoint values of the range. As used herein, ranges specifically include all the integer values of the range. For example, a range of 1 to 100 specifically includes the end point values of 1 and 100. It will be understood that any subranges or individual values in a range or subrange that are included in the description herein can be excluded from the claims herein.

As used herein, “comprising” is synonymous and can be used interchangeably with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” can be replaced with either of the other two terms. The invention illustratively described herein suitably can be practiced in the absence of any element or elements, limitation or limitations which is/are not specifically disclosed herein.

What is claimed is:

1. A method for creating a camouflage pattern, the method comprising:
inputting data into a camouflage pattern generator;
using the camouflage pattern generator to generate a camouflage pattern for a target environment;
applying the camouflage pattern to an object to create a camouflaged object;
placing the camouflaged object in a virtual version of the target environment;
determining a probability that the camouflaged object is present in the virtual version of the target environment; and
when the probability is below a specified threshold, identifying the camouflage pattern as effective for eliminating an object signature.

2. The method of claim 1 carried out by a generative machine learning model.

3. The method of claim 2, wherein the generative machine learning model is selected from the group consisting of a generative adversarial network (GAN), a diffusion model, a flow-matching network, a variational autoencoder, and a transformer-based model.

4. The method of claim 1, further comprising adding noise to the camouflage pattern before applying the camouflage pattern to the object.

5. The method of claim 1, wherein the data comprise a portion of an animal, an entire animal, hair, feathers, stripes, a landscape, a tree(s), leaves, rock(s), water, or a combination thereof.

6. The method of claim 1, wherein the data are selected for the target environment.

7. The method of claim 1, wherein the data are selected for a season of the year.

8. The method of claim 1, wherein the object is selected from the group consisting of a human form, a watercraft, diving equipment, a land vehicle, an aircraft and/or a part of any of the foregoing.

9. The method of claim 1, further comprising applying the camouflage pattern to a substrate.

10. The method of claim 9, wherein the substrate is a material comprising at least one of a thermally emissive layer, a spectrally selective coating, and a conductive fiber system.

11. The method of claim 9, wherein the step of applying is performed in multiple layers to achieve macroscopic texturing.

12. The method of claim 1, further comprising adding a macro pattern to the camouflage pattern to form a hybrid pattern that visually breaks-up the object's form.

13. The method of claim 12, wherein the hybrid pattern is non-repeating.

14. A hybrid camouflage pattern comprising:
a camouflage pattern based on an image of animal hair; and
a macro pattern that breaks the camouflage pattern into non-repeating segments.

15. The hybrid camouflage pattern of claim 14, wherein the macro pattern is a lighter hue than the camouflage pattern.

16. A garment having the hybrid camouflage pattern of claim 14 printed thereon.

17. A method for generating a camouflage pattern, comprising:
training a generative machine learning model on environment-specific data;
applying said camouflage pattern to a simulated form within a virtual environment;
evaluating visibility of the simulated form using multi-spectrum detection models; and
optimizing said camouflage pattern until detection probability falls below a predefined threshold.

18. The method of claim 17, wherein the generative machine learning model is selected from the group consisting of a generative adversarial network (GAN), a diffusion model, a flow-matching network, a variational autoencoder, and a transformer-based model.

19. The method of claim 17, wherein the step of evaluating comprises detecting visible, infrared, and/or ultraviolet spectra.

20. The method of claim 17, further comprising simulating the camouflage pattern under textile conditions including stretching, folding, and/or heat exposure.
